(19) United States
(12) Patent Application Publication
(10) Pub. No.: US 2012/0225554 A1
(43) Pub. Date: Sep. 6, 2012

(54) METHOD OF MANUFACTURING SEMICONDUCTOR DEVICE USING BOWING PREVENTION FILM

(76) Inventors: Kukhan YOON, Hwaseong-si (KR); Cheolkyu LEE, Seongnam-si (KR); Junsoo LEE, Yongin-si (KR); Jong-Kyu KIM, Hwaseong-si (KR); Seong-Mo KOO, Seoul (KR); Ki-jin PARK, Seoul (KR)

(21) Appl. No.: 13/409,169

(22) Filed: Mar. 1, 2012

(30) Foreign Application Priority Data
Mar. 2, 2011 (KR) 10-2011-0018582

(51) Int. Cl. H01L 21/768

(52) U.S. Cl. 438/675; 257/E21.586

(57) ABSTRACT

A method of manufacturing a semiconductor device, the method including sequentially forming a lower material film, a middle material film, and an upper material film on a semiconductor substrate; and forming an opening that vertically penetrates the upper material film, the middle material film, and the lower material film by etching the upper material film, the middle material film, and the lower material film, wherein the middle material film and the upper material film are formed of material films having etch rates lower than an etch rate of the lower material film with respect to an etchant for etching the lower material film.

### CROSS-REFERENCE TO RELATED APPLICATIONS

Korean Patent Application No. 10-2011-0018582, filed on Mar. 2, 2011, in the Korean Intellectual Property Office, and entitled: “Method of Manufacturing Semiconductor Device Using Bowing Prevention Film,” is incorporated by reference herein in its entirety.

### BACKGROUND

1. Field

Embodiments relate to a method of manufacturing a semiconductor device using a bowing prevention film.

2. Description of the Related Art

As the integration of semiconductor devices (e.g., DRAM devices) increases, a height of storage nodes formed in an insulating film likewise increases. To increase the height of the storage nodes, a depth of storage node holes penetrating the insulating film should be increased. In this case, an aspect ratio of the storage node holes may be increased.

### SUMMARY

Embodiments are directed to a method of manufacturing a semiconductor device using a bowing prevention film.

The embodiments may be realized by providing a method of manufacturing a semiconductor device, the method including sequentially forming a lower material film, a middle material film, and an upper material film on a semiconductor substrate; and forming an opening that vertically penetrates the upper material film, the middle material film, and the lower material film by etching the upper material film, the middle material film, and the lower material film, wherein the middle material film and the upper material film are formed of material films having etch rates lower than an etch rate of the lower material film with respect to an etchant for etching the lower material film.

The middle material film may have a first thickness, the upper material film may have a second thickness, and the second thickness may be greater than the first thickness.

A thickness of the lower material film may be greater than a thickness of the middle material film or a thickness of the upper material film.

Forming the opening may include forming an upper opening exposing a top surface of the lower material film by etching the upper material film and the middle material film; and forming a lower opening in the lower material film by etching the lower material film exposed by the upper opening.

The opening may be formed to have a hole shape or a linear shape when viewed from a top plan view.

The method may further include forming a conductive pattern in the opening.

The embodiments may also be realized by providing a method of manufacturing a semiconductor device, the method including sequentially forming a mold film, a support film, and a bowing prevention film on a semiconductor substrate; forming a plurality of holes that penetrate the bowing prevention film, the support film, and the mold film by etching the bowing prevention film, the support film, and the mold film, wherein the bowing prevention film and the support film are formed of material films having etch rates lower than an etch rate of the mold film with respect to an etchant for etching the mold film; and respectively forming a plurality of conductive nodes in the plurality of holes.

Forming the holes may include forming upper openings exposing a top surface of the mold film by etching the support film and the bowing prevention film; and forming lower openings in the mold film by etching the mold film exposed by the upper openings.

The bowing prevention film may be formed of material having an etch rate lower than an etch rate of the support film with respect to an etchant for etching the support film.

The method may further include removing the bowing prevention film after forming the conductive nodes.

The method may further include forming a plurality of supporters exposing the mold film by patterning the support film after removing the bowing prevention film, wherein one end of each of the supporters contacts one of the conductive nodes adjacent thereto, and another end of each of the supporters contacts another of the conductive nodes.

The method may further include removing the mold film, after forming the supporters.

The method may further include forming a dielectric film that covers surfaces of the conductive nodes and a plate electrode that covers the dielectric film, after removing the mold film.

Each of the conductive nodes may be formed to have a cylindrical shape conformally covering a sidewall and a bottom surface of each of the holes.

The mold film may be formed of a silicon oxide film, the support film may be formed of a silicon nitride film, and the bowing prevention film may be formed of a silicon oxynitride film.

The embodiments may also be realized by providing a method of manufacturing a semiconductor device, the method including sequentially forming a lower mold film, a lower support film, and a lower bowing prevention film on a semiconductor substrate; forming a lower hole that penetrates the lower bowing prevention film, the lower support film, and the lower mold film by etching the lower bowing prevention film, the lower support film, and the lower mold film, wherein the lower bowing prevention film and the lower support film are formed of material films having etch rates lower than an etch rate of the lower mold film with respect to an etchant for etching the lower mold film; forming a conductive pattern in the lower hole; sequentially forming an upper mold film, an upper support film, and an upper bowing prevention film on the semiconductor substrate including the conductive nodes thereon; forming a plurality of upper holes that penetrate the upper bowing prevention film, the upper support film, and the upper mold film by etching the upper bowing prevention film, the upper support film, and the upper mold film, wherein the upper bowing prevention film and the upper support film are formed of material films having etch rates lower than an etch rate of the upper mold film with respect to an etchant for etching the upper mold film; and respectively forming a plurality of conductive nodes in the plurality of upper holes.

Forming the lower hole may include forming a first lower opening exposing a top surface of the lower mold film by etching the lower bowing prevention film and the lower support film; and forming a second lower opening in the lower mold film by etching regions of the lower mold film exposed by the first lower opening such that the second lower opening is vertically aligned with the first lower opening.

Forming the upper holes may include, with respect to each upper hole of the upper holes, forming a first upper opening exposing a top surface of the upper mold film by etching the upper bowing prevention film and the upper support film; and forming a second upper opening in the upper mold film by etching regions of the upper mold film exposed by the first upper opening such that the second upper opening is vertically aligned with the first upper opening.

The method may further include removing the upper bowing prevention film after forming the conductive nodes; and forming a plurality of supporters exposing the mold film by patterning the upper support film after removing the upper bowing prevention film, wherein one end of each of the supporters contacts one of the conductive nodes adjacent thereto, and another end of each of the supporters contacts another of the conductive nodes.

The upper mold film may be formed of a silicon oxide film, the upper support film may be formed of a silicon nitride film, and the upper bowing prevention film may be formed of a silicon oxynitride film.

### BRIEF DESCRIPTION OF THE DRAWINGS

The embodiments will become apparent to those of ordinary skill in the art by describing in detail exemplary embodiments with reference to the attached drawings, in which:

FIG. 1A illustrates a top plan view of a semiconductor device in accordance with an embodiment.

FIG. 1B illustrates a top plan view of a semiconductor device in accordance with another embodiment.

FIGS. 2 through 15 illustrate cross sectional views taken along the line I-I′ of FIG. 1A showing stages in a method of manufacturing semiconductor devices in accordance with an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Embodiments may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

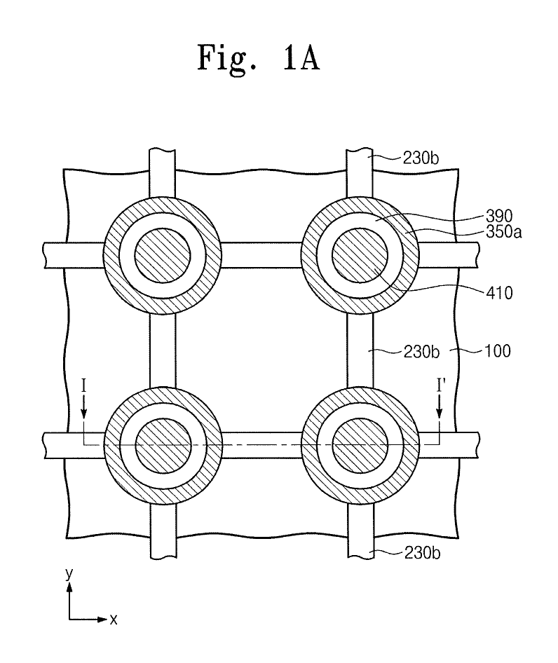

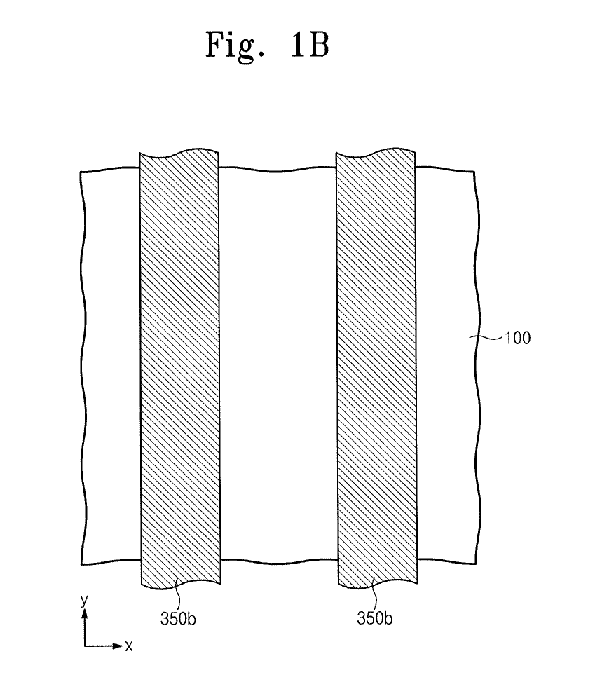

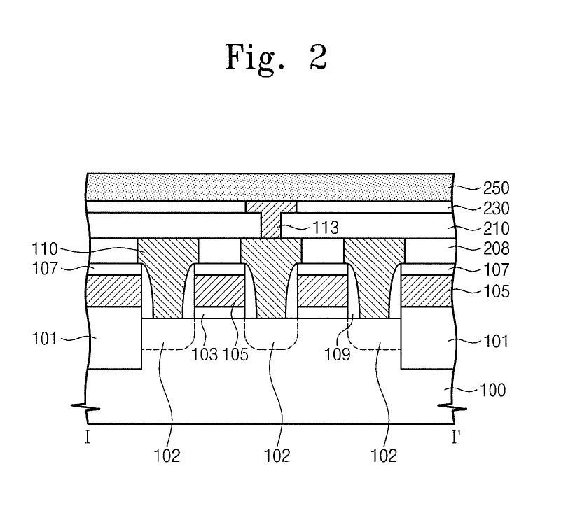

FIG. 1A illustrates a top plan view of a semiconductor device in accordance with an embodiment. FIG. 1B illustrates a top plan view of a semiconductor device in accordance with another embodiment. FIGS. 2 through 15 illustrate cross sectional views taken along the line I-I′ of FIG. 1 showing stages in a method of manufacturing semiconductor devices in accordance with an embodiment.

Methods of manufacturing semiconductor devices according to the embodiments will be explained referring to FIGS. 1A, 1B and 2 through 15.

Referring to FIGS. 1A and 2, a device isolation film 101 (defining an active region) may be formed on a substrate 100. A gate insulating film, a gate conductive film, and a capping insulating film (not illustrated) may be sequentially formed on the substrate 100 having the device isolation film 101 thereon. The capping insulating film, the gate conductive film, and the gate insulating film may be successively patterned to form a plurality of word line patterns crossing the active region and the device isolation film 101. Each of the word line patterns may include a sequentially stacked gate insulating pattern 103, a word line 105, and a capping insulating film pattern 107. An insulating film (not illustrated) may be conformally formed on an entire surface of the substrate 100 including the word line patterns, and then the insulating film may be anisotropically etched to form insulating spacers 109 on sidewalls of the word line patterns. For example, the insulating spacer 109 may include silicon nitride (SiN).

After forming the insulating spacer 109, dopants may be implanted into the active region using the word line pattern and the insulating spacer 109 as an ion implantation mask to form impurity regions 102. The dopants may be n-type dopants. The implanted dopants may be diffused into the substrate 100 by a thermal treatment to form activated impurity regions 102. If the semiconductor device according to an embodiment is applied to a DRAM device, the impurity regions 102 may be used as source regions and drain regions of cell transistors.

An insulating film 208 may be formed on an entire surface of the substrate 100 including the impurity regions 102. The insulating film 208 may be formed of, e.g., a silicon oxide (SiO₂) film. The insulating film 208 may be patterned to form contact holes exposing the impurity regions 102. While etching the insulating film 208 to form the contact holes, the insulating spacer 109 and the capping insulating film pattern 107 may perform a function of an etch-stopper film. For example, the contact holes may correspond to self aligned contact holes. A conductive film (not illustrated) may be formed on an entire surface of the substrate 100 including the contact holes, and then the conductive film may be planarized to expose a top surface of the insulating film 208. As a result, contact pads 110 may be respectively formed in the contact holes. A first lower material film 210 and a first middle material film 230 may be sequentially formed on the substrate 100 including the contact pads 110 thereon.

A bit line 113 (crossing over the word lines 105) may be formed in the first middle material film 230. The bit line 113 may be electrically connected to one of the contact pads 110 through a bit line contact hole penetrating the first lower material film 210. The bit line 113 may be formed using, e.g., a damascene process. A first upper material film 250 may be formed on the substrate 100 including the bit line 113 thereon. The first middle material film 230 may have a first thickness and the first upper material film 250 may have a second thickness. In an implementation, the second thickness of the first upper material film 250 may be greater than the first thickness of the first middle material film 230. In another implementation, the first lower material film 210 may have a thickness greater than the first thickness of the first middle material film 230 or the second thickness of the first upper material film 250.

The first middle material film 230 and the first upper material film 250 may be formed of material films respectively having etching rates lower than an etching rate of the first lower material film 210 during an etching process for etching the first lower material film 210, e.g., with respect to an etchant for etching the first lower material film 210. For example, the first middle material film 230 and the first upper material film 250 may have an etch selectivity with respect to the first lower material film 210.

In an implementation, the first lower material film 210 may be formed of a silicon oxide film (SiO₂) and the first middle material film 230 and the first upper material film 250 may be formed of a silicon nitride film (SiN) and a silicon oxynitride film (SiON) respectively. Alternatively, the first lower material film 210 may be formed of silicon oxide film and the first middle material film 230 and the first upper material film 250 may be formed of a silicon carbon nitride film (SiCN) and a silicon nitride film (SiN), respectively.

The first upper material film 250 may be formed of a material film having an etch rate lower than an etch rate of the first middle material film 230 during an etching process for etching the first middle material film 230, e.g., with respect to an etchant for etching the first middle material film 230. For example, the first upper material film 250 may have an etch selectivity with respect to the first middle material film 230.

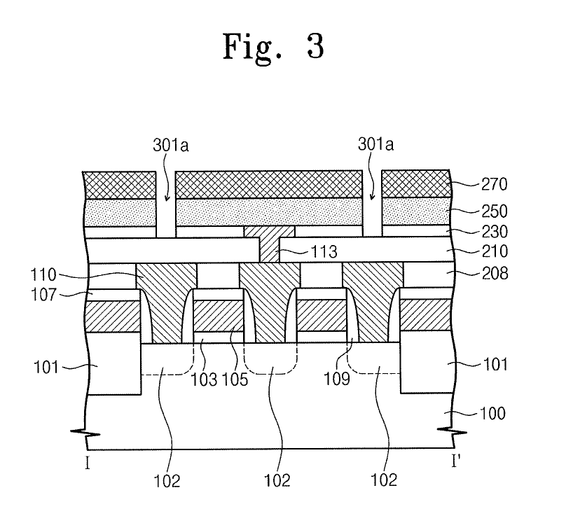

Referring to FIG. 3, a first photo mask 270 may be formed on the first upper material film 250. The first photo mask 270 may have openings disposed over contact pads 110 that are not electrically connected to the bit line 113. In an implementation, the openings of the first photo mask 270 may have a hole shape.

The first upper material film 250 and the first middle material film 230 may be etched using the first photo mask 270 as an etching mask to form a pair of first upper openings 301a. The pair of first upper openings 301a may expose portions, e.g., first and second regions, of the first lower material film 210.

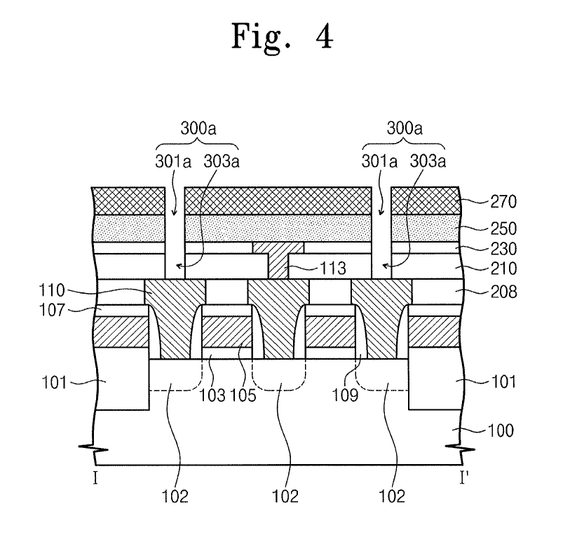

Referring to FIG. 4, the portions of the first lower material film 210 exposed by the first upper openings 301a may be etched to form a pair of first lower openings 303a respectively exposing the contact pads 110 that are not electrically connected to the bit line 113. In an implementation, the first upper openings 301a may be vertically aligned with the first lower openings 303a, e.g., the first upper openings 301a may be connected to or in communication with the first lower openings 303a.

In the case that an aspect ratio of the first upper opening 301a and an aspect ratio of the first lower opening 303a are large, the first material films 210, 230, and 250 may be etched using an etchant that minimizes generation of polymers. Suppression of polymer generation may help ensure a successful formation of not only the first upper openings 301a, but also the first lower openings 303a. For example, if a depth of the first lower openings 303a increases, generation of polymers should be suppressed while etching the first lower material film 210 to form the first lower openings 303a. Suppression of polymer generation while etching the first lower material film 210 to form the first lower openings 303a may help prevent the first lower openings 303a from having an inclined sidewall. Thus, the first lower openings 303a may be formed to have a depth at least as great as a thickness of the first lower material film 210. For example, if generation of polymers is not suppressed while etching the first lower material film 210 (to form the first lower openings 303a), even if a time of an etching process to form the first lower openings 303a is increased, the first lower opening 303a may not completely penetrate the first lower material film 210. Thus, generation of polymer should be suppressed while etching the first lower material film 210 to form the first lower openings 303a so that the first lower openings 303a penetrates the first lower material film 210. If the first middle material film 230 and the first upper material film 250 were to be continuously etched while forming the first lower openings 303a, a width of the first upper openings 303a may be increased while forming the first lower openings 303a, so that a bowing phenomenon could occur.

As described with reference to FIG. 2, the first middle material film 230 and the first upper material film 250 may be formed of material films respectively having etch rates lower than an etch rate of the first lower material film 210 while etching the first lower material film 210, e.g., with respect to an etchant for etching the first lower material film 210. Thus, while forming a first opening 300a (composed of the first upper opening 301a and the first lower opening 303a), a bowing phenomenon may be reduced and/or prevented. In an implementation, the first lower material film 210, the first middle material film 230, and the first upper material film 250 may perform functions of a mold film, a support film, and a bowing prevention film, respectively.

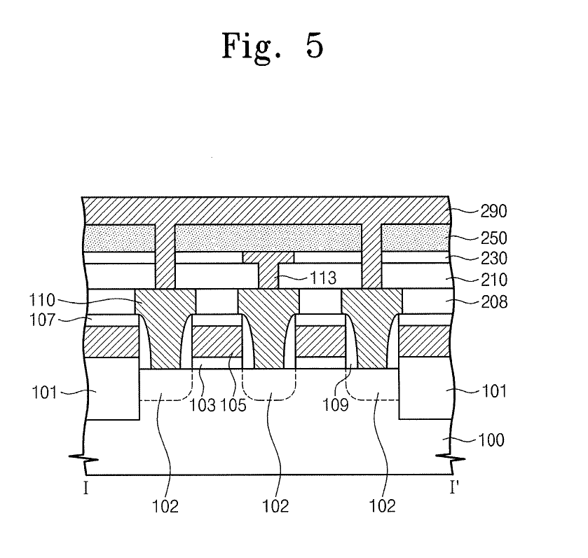

Referring to FIG. 5, after removing the first photo mask 270, a first conductive film 290 may be formed on the substrate 100 including the first openings 300a thereon. The first conductive film 290 may fill the first openings 300a. The first conductive film 290 may include, e.g., a titanium nitride (TiN) film. The first conductive film 290 may be electrically connected to the contact pads 110 (not connected to the bit line 113).

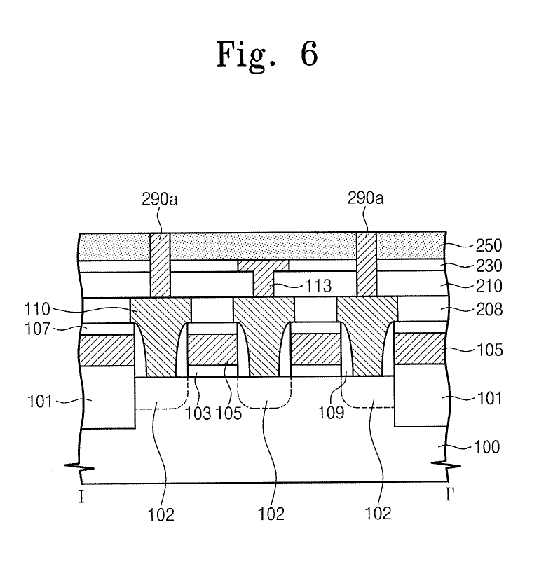

Referring to FIG. 6, the first conductive film 290 may be etched back to expose a top surface of the first upper material film 250. As a result, conductive plugs 290a (respectively filling the first openings 300a) may be formed.

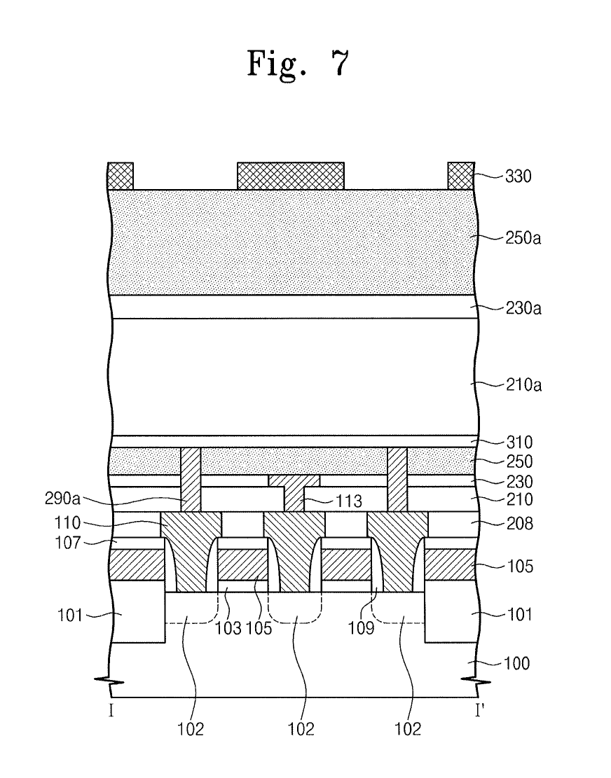

Referring to FIG. 7, an etch-stop film 310, a second lower material film 210a, a second middle material film 230a, and a second upper material film 250a may be sequentially formed on the substrate 100 including the conductive plugs 290a thereon. The etch-stop film 310 may be formed of, e.g., a silicon nitride film (SiN). In an implementation, the etch-stop film 310 may be omitted. The second lower material film 210a, the second middle material film 230a, and the second upper material film 250a may be formed of the same material film as the first lower material film 210, the first middle material film 230, and the first upper material film 250 of FIG. 2, respectively. For example, the second lower material film 210a, the second middle material film 230a, and the second upper material film 250a may perform functions of a mold film, a support film, and a bowing prevention film, respectively. In addition, the second upper material film 250a may also be thicker than the second middle material film 230a. The second lower material film 210a may be thicker than the second middle material film 230a or the second upper material film 250a.

A second photo mask 330 may be formed on the second upper material film 250a. The second photo mask 330 may have openings respectively disposed over the conductive plugs 290a.

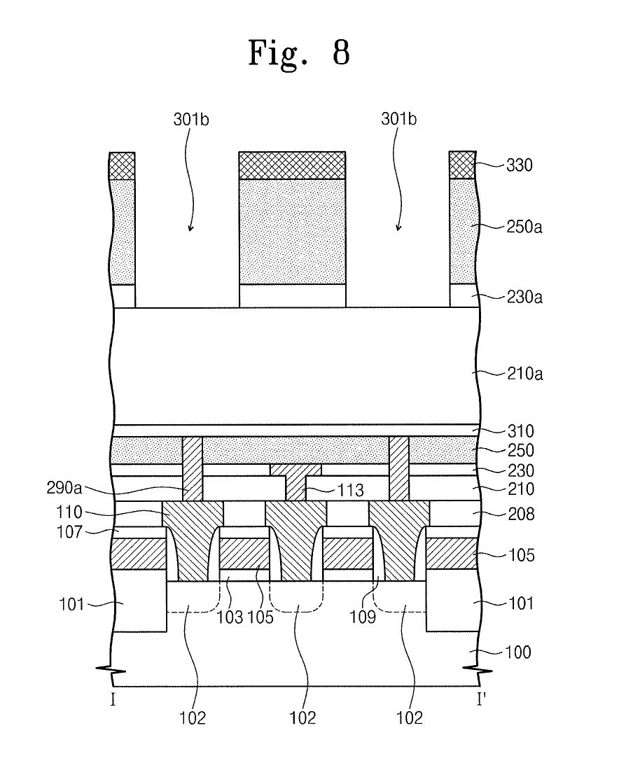

Referring to FIG. 8, the second upper material film 250a and the second middle material film 230a may be sequentially etched (using the second photo mask 330 as an etching mask) to form a pair of second upper openings 301b exposing first and second regions of the second lower material film 210a, respectively.

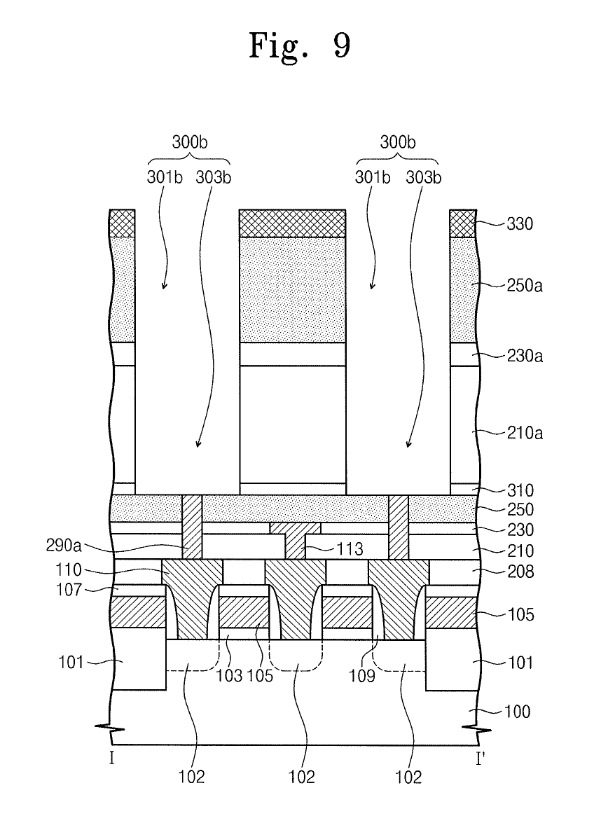

Referring to FIG. 9, portions of the second lower material film 210a (exposed by the second upper opening 301b) and the etch-stop film 310 (under the second lower material film 210a) may be successively etched to form second lower openings 303b respectively exposing the conductive plugs 290a. The second upper opening 301b and the second lower opening 303b may constitute a second opening 300b. For example, the second upper opening 301b and the second lower opening 303b may be vertically aligned or connected with one another. In an implementation, the second openings 300b may correspond to storage node holes of DRAM cells. The second openings 300b may be formed using the same method for forming the first openings 300a described with reference to FIGS. 3 and 4. Accordingly, while forming the second opening 300b, a bowing phenomenon may be reduced and/or prevented. Thus, reduction of a distance between the second openings 300b (i.e., a distance between the storage node holes) may be prevented.

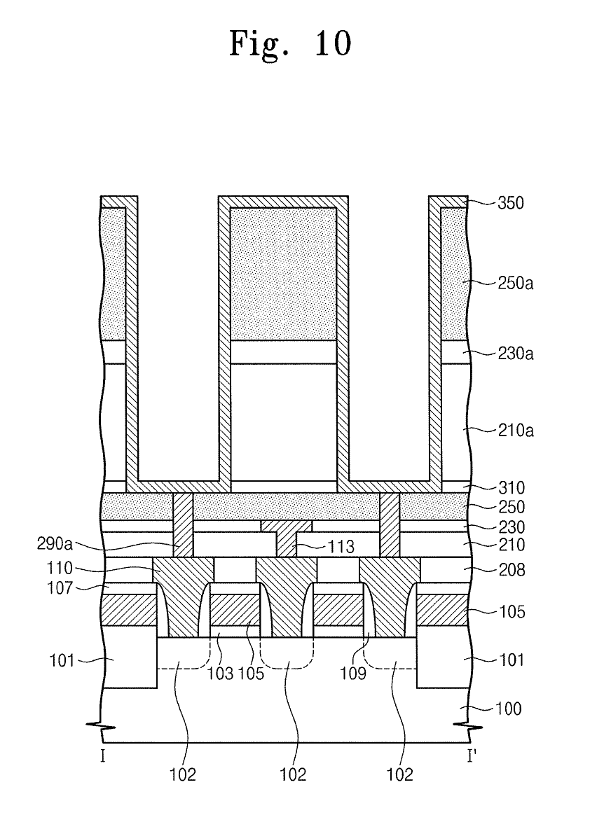

Referring to FIG. 10, after removing the second photo mask 330, a second conductive film 350 may be formed on an entire surface of the substrate 100 including the second openings 300b thereon. The second conductive film 350 may be conformally formed. The second conductive film 350 may include, e.g., a titanium nitride film (TiN).

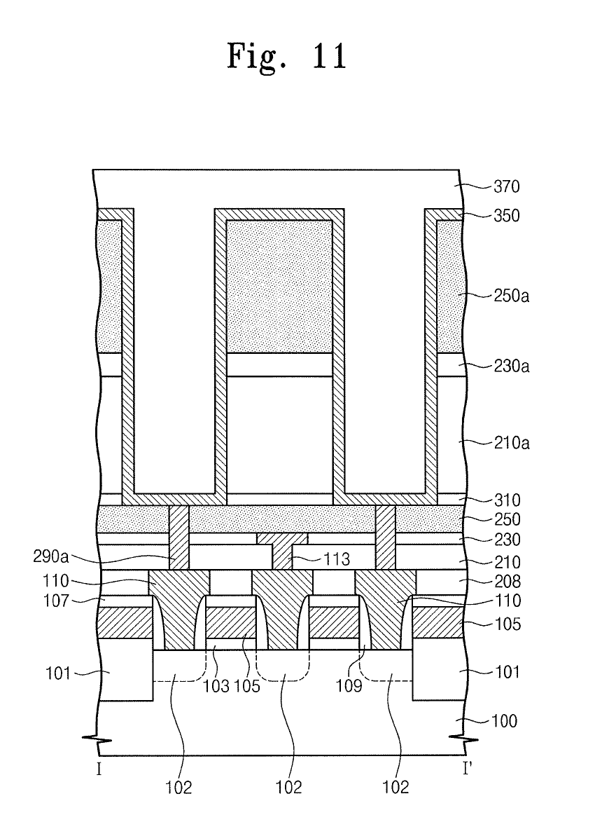

Referring to FIG. 11, a sacrificial film 370 may be formed on the second conductive film 350. The sacrificial film 370 may be formed of the same material film as the second upper material film 250a.

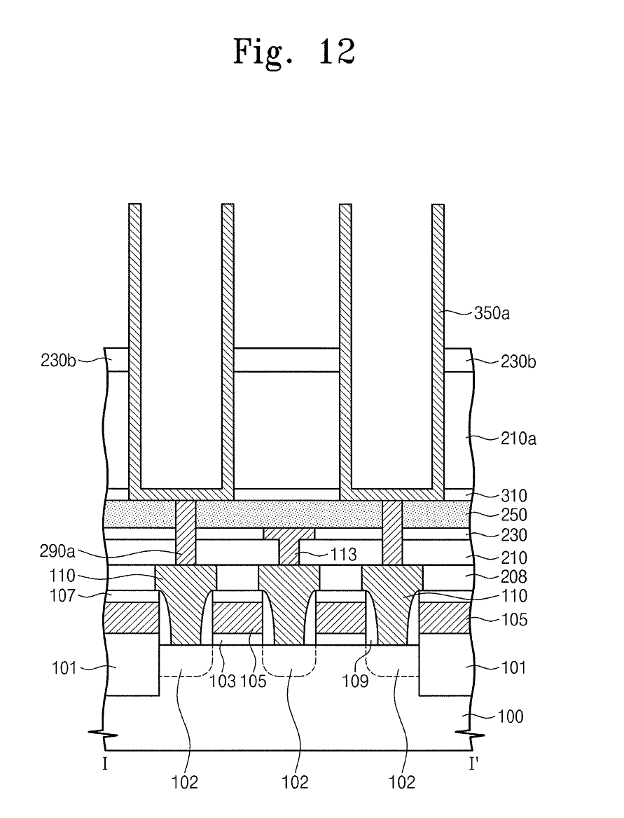

Referring to FIG. 12, the sacrificial film 370 and the second conductive film 350 may be etched back to expose a top surface of the second upper material film 250a. As a result, conductive nodes 350a (separated from one another) may be formed in the second openings 300b. For example, the conductive nodes 350a may be storage nodes having a cylindrical shape. Etching back the sacrificial film 370 and the second conductive film 350 may be performed using, e.g., a chemical mechanical polishing (CMP) technique.

After forming the conductive nodes 350a, residue of the sacrificial film and the second upper material film 250a may be removed to expose the second middle material film 230a. Subsequently, a spin on hard mask (SOH) layer may be formed on the resultant structure, and a hard mask film, e.g., a silicon oxide film, may be formed on the spin on hard mask (SOH) layer. In an implementation, the spin on hard mask (SOH) layer may be a carbon-based SOH layer.

The hard mask film may be patterned to form a hard mask pattern that exposes a part of the spin on hard mask (SOH) layer. The spin on hard mask (SOH) layer may be etched using the hard mask pattern as an etching mask to expose a part of the second middle material film 230a. Subsequently, the exposed portions of the second middle material film 230a may be etched to form supporters 230b that expose the second lower material film 210a. The supporters 230b may perform a function of preventing the storage nodes 350a from leaning in a subsequent process. For example, as illustrated in FIG. 1A, respective ends of the supporter 230b may contact conductive nodes 350a adjacent to the supporter 230b. After forming the supporters 230b, the hard mask pattern and a residue of the spin on hard mask (SOH) layer may be removed.

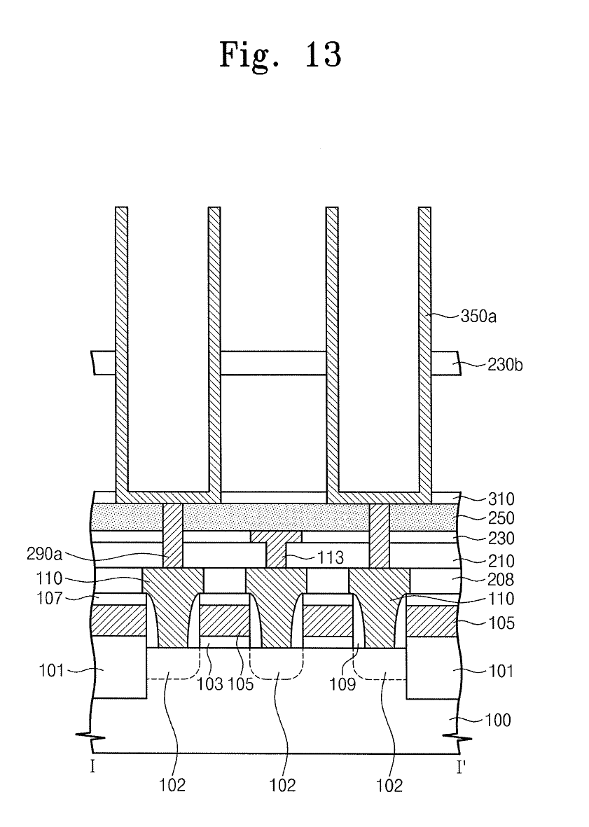

Referring to FIG. 13, after forming the supports 230b, the second lower material film 210a may be removed. As a result, lower and outer sidewalls of the conductive nodes 350a may be exposed.

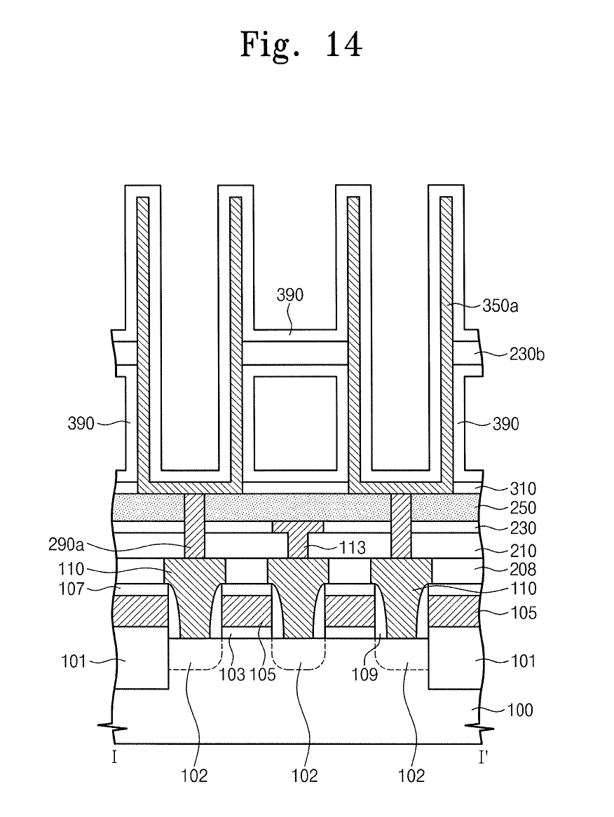

Referring to FIG. 14, a dielectric film 390 may be conformally formed on an entire surface of the resultant structure (in which the second lower material film 210a has been removed). The dielectric film 390 may be a high-k dielectric layer having dielectric constant higher than silicon oxide (SiO₂). For example, the dielectric film 390 may include a hafnium oxide film (HfO₂) and/or lanthanum oxide film (La₂O₃).

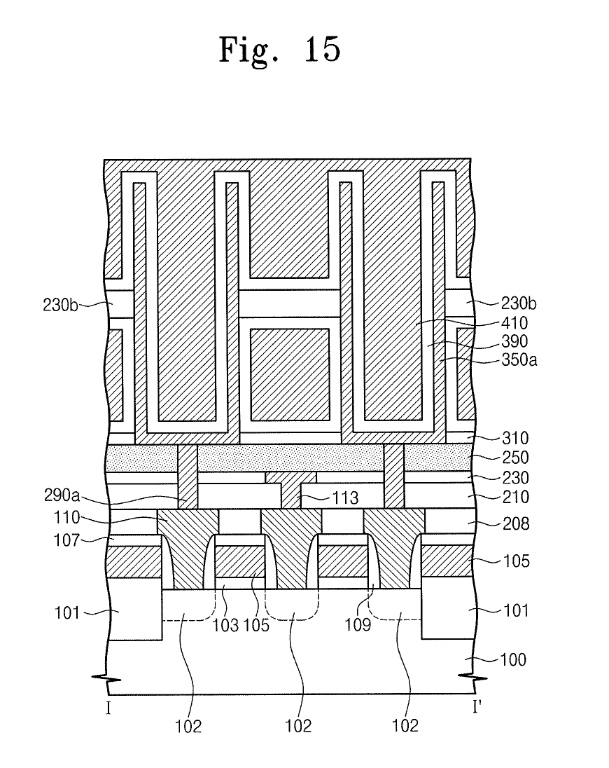

Referring to FIG. 15, an upper conductive node 410 (e.g., a plate electrode) may be formed on an entire surface of the substrate 100 including the dielectric film 390 thereon. For example, the upper conductive node 410 may be formed of titanium nitride (TiN).

In the embodiments, the first openings 300a and the second openings 300b are not limited to contact holes or storage node holes. For example, the first openings 300a and/or the second openings 300b may be formed to have various shapes other than a hole. In an implementation, the first openings 300a and/or the second openings 300b may be formed to have a linear shape. In this case, as illustrated in FIG. 1B, interconnection lines 350b of a line shape may be formed in the first openings 300a and/or the second openings 300b.

By way of summation and review, DRAM devices may include storage nodes having a high and narrow shape in a limited plan area to improve integration and cell characteristics. The storage nodes may lean during a subsequent process, e.g., a spin dry process. As a result, some of the storage nodes may contact one another to cause an electrical shortage.

In order to suppress a leaning effect of the storage nodes, a method of forming insulating supporters between the storage nodes has been considered. According to a method of forming a DRAM cell including the insulating supporters, a lower oxide film, a support film, and an upper oxide film may be sequentially formed on a semiconductor substrate. The lower oxide film, the support film, and the upper oxide film may be etched to form a plurality of storage node holes. Etching to form the storage node holes may be performed using an etchant that suppresses generation of polymers so that the storage node holes may completely penetrate the upper oxide film, the support film, and the lower oxide film.

When etching the insulating film to form the storage node holes having a high aspect ratio, a bowing phenomenon may occur. If a bowing phenomenon occurs, a distance between the adjacent storage node holes may be reduced and thereby a leakage current characteristic between storage nodes formed in the respective storage node holes may be deteriorated. In addition, an electrical short between storage nodes in the storage node holes may occur.

According to an embodiment, a middle material film and an upper material film may be formed of material films having an etch rate lower than an etch rate of a lower material film while the lower material film is etched, e.g., with respect to an etchant for etching the lower material film. For example, the middle material film and the upper material film may have an etch selectivity with respect to the lower material film. Thus, when forming an opening having a high aspect ratio that penetrates the upper material film, the middle material film, and the lower material film, an undesirable bowing phenomenon may be reduced an/or prevented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a semiconductor device, the method comprising:
sequentially forming a lower material film, a middle material film, and an upper material film on a semiconductor substrate; and
forming an opening that vertically penetrates the upper material film, the middle material film, and the lower material film by etching the upper material film, the middle material film, and the lower material film,
wherein the middle material film and the upper material film are formed of material films having etch rates lower than an etch rate of the lower material film with respect to an etchant for etching the lower material film.

2. The method as claimed in claim 1, wherein:
the middle material film has a first thickness,
the upper material film has a second thickness, and
the second thickness is greater than the first thickness.

3. The method as claimed in claim 1, wherein a thickness of the lower material film is greater than a thickness of the middle material film or a thickness of the upper material film.

4. The method as claimed in claim 1, wherein forming the opening includes:
forming an upper opening exposing a top surface of the lower material film by etching the upper material film and the middle material film; and
forming a lower opening in the lower material film by etching the lower material film exposed by the upper opening.

5. The method as claimed in claim 1, wherein the opening is formed to have a hole shape or a linear shape when viewed from a top plan view.

6. The method as claimed in claim 1, further comprising forming a conductive pattern in the opening.

7. A method of manufacturing a semiconductor device, the method comprising:
sequentially forming a mold film, a support film, and a bowing prevention film on a semiconductor substrate;
forming a plurality of holes that penetrate the bowing prevention film, the support film, and the mold film by etching the bowing prevention film, the support film, and the mold film, wherein the bowing prevention film and the support film are formed of material films having etch rates lower than an etch rate of the mold film with respect to an etchant for etching the mold film; and
respectively forming a plurality of conductive nodes in the plurality of holes.

8. The method as claimed in claim 7, wherein forming the holes includes:
forming upper openings exposing a top surface of the mold film by etching the support film and the bowing prevention film; and
forming lower openings in the mold film by etching the mold film exposed by the upper openings.

9. The method as claimed in claim 7, wherein the bowing prevention film is formed of material having an etch rate lower than an etch rate of the support film with respect to an etchant for etching the support film.

10. The method as claimed in claim 7, further comprising removing the bowing prevention film after forming the conductive nodes.

11. The method as claimed in claim 10, further comprising forming a plurality of supporters exposing the mold film by patterning the support film after removing the bowing prevention film,
wherein one end of each of the supporters contacts one of the conductive nodes adjacent thereto, and another end of each of the supporters contacts another of the conductive nodes.

12. The method as claimed in claim 11, further comprising removing the mold film, after forming the supporters.

13. The method as claimed in claim 12, further comprising forming a dielectric film that covers surfaces of the conductive nodes and a plate electrode that covers the dielectric film, after removing the mold film.

14. The method as claimed in claim 7, wherein each of the conductive nodes is formed to have a cylindrical shape conformally covering a sidewall and a bottom surface of each of the holes.

15. The method as claimed in claim 7, wherein:
the mold film is formed of a silicon oxide film,
the support film is formed of a silicon nitride film, and
the bowing prevention film is formed of a silicon oxynitride film.

16. A method of manufacturing a semiconductor device, the method comprising:
sequentially forming a lower mold film, a lower support film, and a lower bowing prevention film on a semiconductor substrate;
forming a lower hole that penetrates the lower bowing prevention film, the lower support film, and the lower mold film by etching the lower bowing prevention film, the lower support film, and the lower mold film, wherein the lower bowing prevention film and the lower support film are formed of material films having etch rates lower than an etch rate of the lower mold film with respect to an etchant for etching the lower mold film;
forming a conductive pattern in the lower hole;
sequentially forming an upper mold film, an upper support film, and an upper bowing prevention film on the semiconductor substrate including the conductive nodes thereon;
forming a plurality of upper holes that penetrate the upper bowing prevention film, the upper support film, and the upper mold film by etching the upper bowing prevention film, the upper support film, and the upper mold film, wherein the upper bowing prevention film and the upper support film are formed of material films having etch rates lower than an etch rate of the upper mold film with respect to an etchant for etching the upper mold film; and
respectively forming a plurality of conductive nodes in the plurality of upper holes.

17. The method as claimed in claim 16, wherein forming the lower hole includes:
forming a first lower opening exposing a top surface of the lower mold film by etching the lower bowing prevention film and the lower support film; and
forming a second lower opening in the lower mold film by etching regions of the lower mold film exposed by the first lower opening such that the second lower opening is vertically aligned with the first lower opening.

18. The method as claimed in claim 16, wherein forming the upper holes includes, with respect to each upper hole of the upper holes:
forming a first upper opening exposing a top surface of the upper mold film by etching the upper bowing prevention film and the upper support film; and
forming a second upper opening in the upper mold film by etching regions of the upper mold film exposed by the first upper opening such that the second upper opening is vertically aligned with the first upper opening.

19. The method as claimed in claim 16, further comprising:
removing the upper bowing prevention film after forming the conductive nodes; and
forming a plurality of supporters exposing the mold film by patterning the upper support film after removing the upper bowing prevention film,
wherein one end of each of the supporters contacts one of the conductive nodes adjacent thereto, and another end of each of the supporters contacts another of the conductive nodes.

20. The method as claimed in claim 16, wherein:
the upper mold film is formed of a silicon oxide film,
the upper support film is formed of a silicon nitride film, and
the upper bowing prevention film is formed of a silicon oxynitride film.
